(19) United States
(12) Patent Application Publication
(10) Pub. No.: US 2014/0306785 A1
(43) Pub. Date: Oct. 16, 2014

(54) HOUSING WITH EXTENDED CREEP AND AIR-STRETCH

(71) Applicant: SUMIDA Components & Modules GmbH, Obernzell (DE)

(72) Inventors: Herbert MAIER, Passau (DE); Thomas Steininger, Hauzenberg (DE)

(21) Appl. No.: 14/250,598

(22) Filed: Apr. 11, 2014

(30) Foreign Application Priority Data
Apr. 11, 2013 (DE) 10 2013 206 453.5

(51) Int. Cl. H05K 5/02; H05K 5/03

(52) U.S. Cl. CPC H05K 5/0247; H05K 5/03
USPC 336/90; 174/556

(57) ABSTRACT

The present invention relates to a housing (100) for receiving an electric component, comprising a hollow housing body (110) with an opening (OS) on one side, which is characterized by a bottom (B) underneath the opening (OS), a lid (D) above the opening (OS), and two side walls (AS1, AS2) adjacent to the opening (OS), and at least two electric contacts (120a to 120f) provided on the bottom (B) of the housing body (110) on opposite housing sides, wherein a first contact (120a) of the electric contacts (120a to 120f) is situated in the region of the opening (OS).

The present invention relates to a housing for receiving an electric component according to the introductory part of claim 1, and in particular to a compact housing which complies with the safety standards for high voltages, as well as to an electric component used by said housing.

The use of electric components which are operated at high voltages (more than 200 V), or which may be subject to high-voltage peaks, requires the adherence to specified distances between the connecting contacts so as to ensure a safe operation. Here, a difference has to be made between the air gap and the creepage distance. The air gap is defined as the shortest distance in the air between two conductive parts. The creepage distance is defined as the shortest distance along the surface of an insulating material between two conductive parts. In general, the creepage distance for a certain voltage value has to be clearly longer than the air gap. The minimum requirements for the required air gaps, respectively, creepage distances depend on the used insulating materials, on the contamination category and the occurring voltages. The required values for the minimum air gap and the minimum creepage distance are specified, for instance, in DIN EN 60 558-2-15.

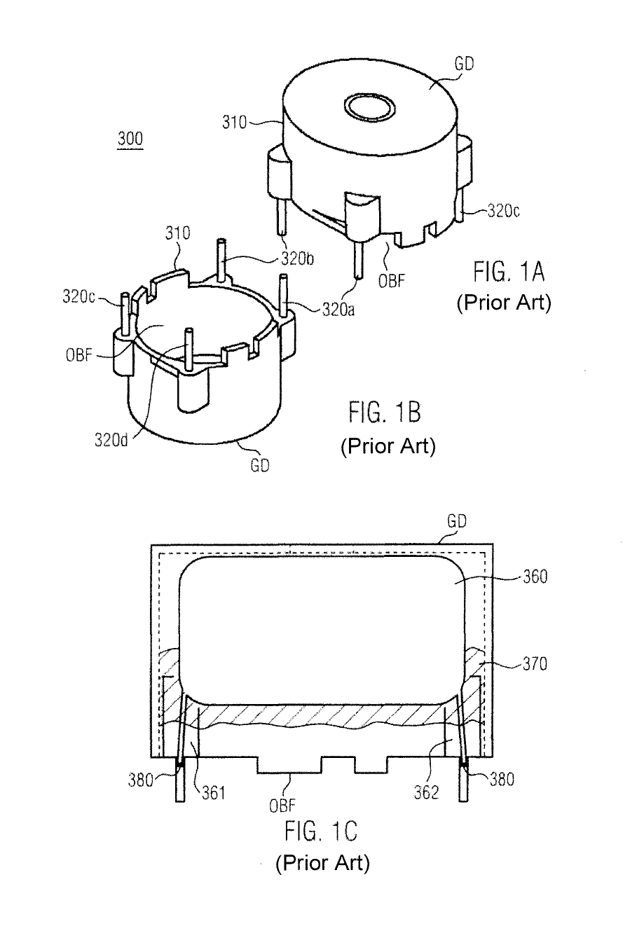

FIG. 1 shows an example of a transformer housing. FIG. 1a shows a perspective view from the top, and FIG. 1b shows a perspective view from the bottom. FIG. 1c shows a transparent lateral view of the housing, with a view to the coil 360 in the interior. The dashed line in FIG. 1c indicates the thickness of the housing wall of the hollow housing.

The housing is a substantially cylindrical hollow body open on one side. The open side defines the bottom surface OBF. The closed lid GD is positioned opposite the open bottom surface OBF. Contact pins 320a, 320b, 320c and 320d are embedded in the housing, at the edge of the open bottom surface OBF, and project vertically out of the bottom surface. The coil form 360 is inserted into the hollow space of the housing through the open bottom surface OBF, and the connecting wires 361 and 362 of the coil are electrically connected to the contact pins 320a-320d. The hollow space between the coil form and the open bottom surface OBF is filled, at least partially, with an electrically insulating filling compound 370.

Thus, the air gap realized for the housing 300 in FIG. 1 is the distance between two contact pins, e.g. between pin 320a and in 320d. The creepage distance additionally includes two times the distance A between the filling material 370 and the attachment 380 of the connecting wire 361 to the contact pin 320a. Hence, the arrangement shown in FIG. 1c has a creepage distance that is longer by about 25% than the air gap. As the creepage distance at a specific desired operating voltage has to be clearly higher than the air gap, subject to the degree of contamination and insulating materials used, the electric strength is substantially determined by the creepage distance. Thus, if the improvement of the electric strength of the housing 300 of FIG. 1 is desired, this may be achieved by increasing the creepage distance.

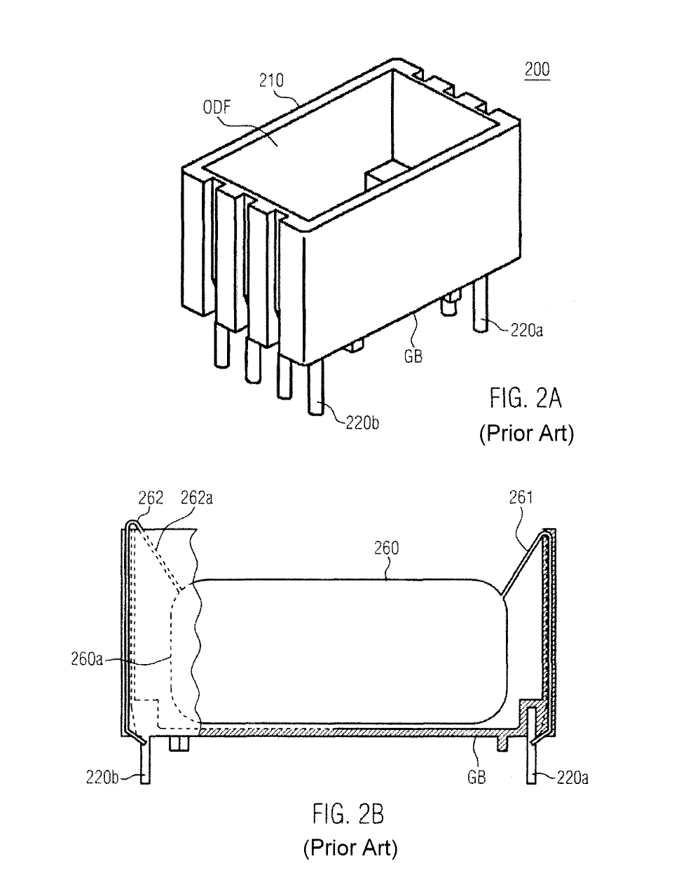

This is realized, for instance, in the housing according to FIG. 2. FIG. 2a shows a perspective view of the housing from the top, and FIG. 2b shows a partial cutaway lateral view of the housing, with a view to the coil 260. As opposed to the housing body 310 of FIG. 1, the housing body 210 is open towards the top, with an open lid surface ODF. Electric contact pins 220a, 220b are embedded in the closed bottom GB. The connecting wires 261 and 262 of the coil 260 are passed through the open lid surface ODF over the upper edge of the housing and along the outside of the housing to the contact pins 220a and 220b. FIG. 2b shows two possible embodiments for laying the connecting leads 261 and 262. Connecting lead 261 is guided inside the housing wall. Connecting lead 262 is guided outside the housing. The dashed lines 260a and 262a in FIG. 2b show the covered parts of the coil 260 and of the connecting wire 262. As opposed to the housing of FIG. 1 the creepage distance in FIG. 2b is increased by double the height of the housing. Similar to the housing of FIG. 1, the hollow space in the housing of FIG. 2 between the coil 260 and the open lid surface ODF is filled, at least partially, with an insulating filling material (not shown in FIG. 2b).

Although the creepage distance in the housing of FIG. 2 is clearly extended as opposed to the housing of FIG. 1 the overall height of the housing of FIG. 2 has to be relatively high in order to provide the room for the filling material for closing the open lid. In comparison with the prior art a housing would be desirable that has a low design and an extended creepage distance and air gap.

It is the object of the present invention to provide a height-optimized housing and a corresponding electric component, with an additional extension of the creepage distances and air gaps.

The object is achieved by a housing comprising the features of patent claim 1. The object is also achieved by an electric component comprising the features of patent claim 10. Preferred embodiments are defined in the dependent patent claims.

According to the invention the object is, in detail, achieved by a housing comprising a hollow housing body with an opening on one side, wherein the opening defines a front side of the housing. The housing is characterized in that the housing bottom includes a bottom underneath the opening, a lid above the opening, and two side walls adjacent to the opening. Furthermore, at least two electric contacts, provided on the bottom of the housing body on opposite housing sides, are located on the housing, wherein a first contact is situated in the region of the opening.

This arrangement allows a reduction of the overall height and, at the same time, an extension of the creepage distances and air gaps in comparison with the the prior art according to FIGS. 1 and 2. Thus, it is possible to obtain a high electric strength even for SMD housings (Surface Mounted Device) for the surface mounting on printed circuit boards. In this case, the electric contacts may project laterally out of the bottom and extend substantially parallel to the bottom.

In one embodiment the housing according to the invention further includes a guiding device on at least one of the adjacent side walls so as to allow a lead to be fixed to the adjacent side wall from the opening towards the housing side situated opposite the opening. Below, the housing side situated opposite the opening will also be referred to as the rear side of the housing.

In another embodiment the housing wall on the rear side of the housing is curved to follow the curvature of a coil, e.g. a toroidal coil with or without a toroidal core, which can be inserted into the housing. Thus, the electric component, the coil, is fixed in the housing in a better and reproducible manner, so that the components are scattered to a smaller extent.

In one embodiment the guiding device is realized in the form of two projections running in parallel so as to define an enclosure for the lead from the opening to the rear side of the housing. Thus, a clear extension of the creepage distance is possible. The extension of the creepage distance can be maximized if the guiding device is arranged, at least partially, at an adjacent region of the opening, facing the lid, on the adjacent side wall.

In a specific embodiment thereof the two projections running in parallel extend from the opening, parallel to the lid, at least to the center, preferably up to three quarters of the adjacent side wall, and the guiding device further comprises a shoulder which extends from the end of the projection, facing away from the opening, ramp-like in the direction of the rear side of the housing and the bottom so as to extend the guiding device up to a second contact of the electric contacts in a region of the rear side of the housing.

The projections running in parallel and the shoulder allow a lead to be reproducibly fixed to the outside of the housing. The shoulder leaves enough play for the lead so that it can be easily soldered to the contact pin.

The housing described above is suited for an SMD configuration where the contact pins are potted with the housing in an SMD grid dimension.

It is an advantage for the manufacture of the housing if the housing body is a single-piece molded part manufactured, for instance, in an injection molding process.

The above-defined object is also achieved by an electric component used by the above-described housing according to the invention, in which at least one coil is incorporated. A first connecting lead of the coil is electrically connected through the opening to the first contact in the region of the opening, and a second connecting lead of the coil is electrically connected through the opening to a second contact in the region of the rear side of the housing. Thus, the air gap between the coil terminals is maximized.

In one embodiment two coils are installed in the housing, e.g. on a common toroidal core, so as to realize, for instance, a transformer or a component for the galvanic isolation. In this embodiment respectively one connecting lead of each coil is passed through the opening of the housing, out of the housing, and electrically connected to an electric contact in the bottom region at the opening of the housing. The respective other connecting lead of each coil is passed through the opening of the housing, out of the housing, and is guided by corresponding guiding devices on both sides of the opening along the adjacent side walls to the rear side of the housing, and electrically connected to a corresponding electric contact in the region of the rear side of the housing. The respective two connecting leads of the two coils, which are guided from the opening of the housing to the rear side of the housing, are laid on opposite housing sides by means of a first and a second guiding device. Thus, a compact transformer for high operating voltages, usable for surface mounting, can be realized. For instance, the component may be realized for an operating voltage of more than 1 kV. If the distance between two electric terminals for a coil is 9.5 mm, the component can be used for a test voltage of up to 9.5 kV, wherein the test voltage is higher than the operating voltage and is specified, in a rule, by a safety standard, e.g. VDE, EN, IEC or UL. If the height of the coil is, for instance, about 5.2 mm the component height may be limited to 8.2 mm.

Through the lateral opening of the housing, through which the connecting leads are passed out, an extension of the air gap is obtained on the one hand, and by guiding the other connecting lead back on the outside of the housing to the opposite side an extension of the creepage distance is obtained on the other hand. At the same time, it is possible to obtain a small overall size, as the housing need not be filled either at the top or at the bottom. In the present invention the covering with a sealing resin is accomplished on the sides.

In one embodiment the at least one coil is wound onto a toroidal core so that it can be retained in the housing without play if the rear wall of the housing is curved. The reproducibility and scattering of components are thus improved. The coil may also be wound onto a frame core or E-core, with the curvature of the rear wall being designed correspondingly.

In another embodiment a hollow space of the housing body between the at least one coil and the opening is filled, at least partially, with a filling compound (170), subject to the standards with regard to overvoltage and contamination categories. Thus, the coil is fixed and protected, and the electric strength may be improved.

Further developments, advantages and possible applications of the invention are also described below by means of embodiments, and are shown in the figures. All features described and/or graphically illustrated, individually or optionally combined, are basically subject matter of the invention, regardless of their summary in the claims or their dependencies. At the same time, the content of the claims is a part of the description.

The invention will be explained in more detail below by means of exemplary embodiments and with the aid of the accompanying figures, wherein:

FIG. 1a shows a perspective top view of a housing for an electric component according to the prior art;

FIG. 1b shows a perspective bottom view of the housing of FIG. 1a;

FIG. 1c shows a transparent lateral view of the housing according to FIG. 1a and 1b;

FIG. 2a shows a perspective top view of another housing according to the prior art;

FIG. 2b shows a partial cutaway lateral view of the housing according to FIG. 2a;

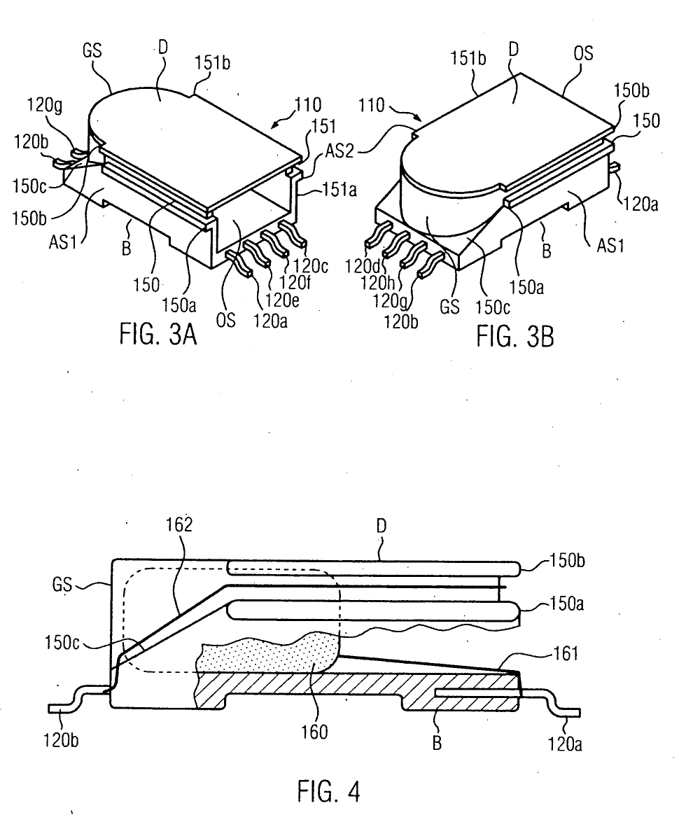

FIG. 3a shows a perspective view of a housing according to the present invention;

FIG. 3b shows another perspective view of a housing according to the present invention;

FIG. 4 shows a partial cutaway lateral view of a housing according to the present invention; and

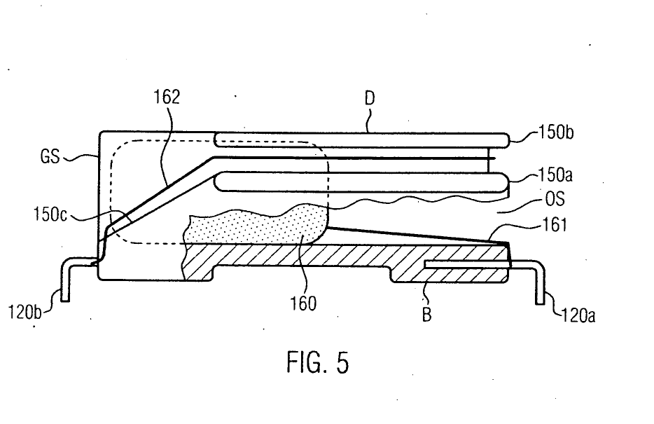

FIG. 5 shows a modification of the embodiment of FIG. 4.

FIGS. 3a and 3b show perspective views from different directions of an example of a housing according to the present invention. FIG. 4 shows a partial cutaway lateral view of an electric component according to the present invention. The electric component comprises the housing according to FIG. 3, in which a component 160 is installed, e.g. a wound core which is also referred to as a coil form.

In FIGS. 3a and 3b reference number 110 designates the housing body, reference numbers 120a-120g designate electric contacts, and reference numbers 150 and 151 designate guiding devices for fixing connecting leads. The housing body 110 is a body that is open on one side and closed on the other sides. In FIGS. 3a and 3b reference number OS designates the opening of the housing body, reference number D designates the lid of the housing, B designates the bottom of the housing, GS designates the closed rear wall of the housing opposite the opening, AS1 and AS2 designate the side walls adjacent to the opening and arranged vertically to the bottom, respectively, to the lid.

The opening defines a front side of the housing, and the side opposite the opening defines a rear side of the housing. The terms rear side of the housing and rear wall of the housing are not used as synonyms. The term rear wall of the housing designates a structural element of the housing, while the term rear side of the housing designates a position. Rear wall of the housing implies a flat structure which extends across the entire width of the housing. In the embodiments according to FIGS. 3 and 4 the rear wall of the housing on the rear side of the housing is curved, so that the changeover from the rear wall of the housing to the adjacent side wall does not have an acute delimitation. Therefore, a part of the rear wall of the housing GS may also be understood as a part of the adjacent side wall ASW1 and ASW2. In a specific embodiment also conically tapered adjacent side walls ASW1 and ASW2 are conceivable. In this case, there is no clearly delimited rear housing wall, while the rear side of the housing is still the side opposite the opening.

FIGS. 3a and 3b each show a guiding device 150, respectively, 151 on each adjacent side walls AS1 and AS2 by means of which a connecting lead can be fixed from the opening OS to the electric contacts 120b, 120d, 120g, 120h in the region of the rear wall of the housing GS. Each guiding device is substantially formed of three parts: an upper projection 150b, respectively 151b, a lower projection 150a, respectively, 151a, and a shoulder 150c, respectively, 151c. The upper projection 150b, respectively, 151b extends each on an adjacent side wall AS1, respectively, AS2 from the opening OS up to about three quarters along the closed lid D. The lower projection 150a, respectively, 151a extends underneath thereof, parallel to the upper projection 150b, respectively, 151b, and has substantially the same length. The distance between the upper projection 150b, respectively, 151b and the lower projection 150a, respectively, 151a is chosen in such a manner that a connecting lead can be received with as little play as possible. For instance, the distance may be 1 mm for a connecting lead having a diameter of 1 mm. A shoulder 150c, respectively, 151c extends from the end of the lower projection 150a, respectively, 151a, facing away from the opening, towards the electric contacts 120b, 120d, 120g and 120h in the region of the rear housing wall GS of the housing. Expressed in more general words, the shoulder 150c, respectively, 151c extends from this end of the lower projection 150a, respectively, 151a in a ramp-like shape downwardly inclined to the contacts in the region of the rear side of the housing.

In FIGS. 3a and 3b the rear housing wall GS is semicircular or curved, so that the shoulder 150c, respectively, 151c widens in the direction of the electric contacts.

The bottom B of the housing has such a thickness that allows the electric contacts 120a to 120h to be potted therein. For instance, the bottom B may have a thickness of 1.5 mm. The electric contacts 120a to 120h are mounted laterally in the bottom B on the opening OS and on the rear wall of the housing GS or, in more general words, on the rear side of the housing.

In FIGS. 3a and 3b four contacts are respectively provided on the opening OS and the rear wall of the housing GS. It is also possible, however, to mount more than four contacts on each side, or fewer contacts, e.g. two contacts, on each side.

It is also possible that the rear wall of the housing GS is flat on the outside and curved on the inside, allowing the inside to follow the curvature of the coil form.

The projections may extend up to the center of the housing, or up to the rear side of the housing.

As an alternative to fixing the connecting lead between the projections, it is also possible to realize the fixing by a recess/indentation in the adjacent side walls AS1, respectively, AS2.

The projections 150a, 150b, 151a, 151b, respectively, the above-mentioned recess may run parallel to the lid D, or run from the lid D to the bottom B downwardly inclined. If the projections/recess run(s) in parallel they may run in the center, in the proximity of the lid or in the proximity of the bottom of the adjacent side walls AS1, respectively, AS2. If they run in the proximity of the lid this will result in the longest creepage distances, however.

The embodiment shown in FIGS. 3a and 3b has the advantage that the creepage distance is slightly longer, as compared to an embodiment where the projections/recess run(s) in the center, in the proximity of the bottom or from the lid D to the bottom B downwardly inclined.

FIG. 4 shows a partial cutaway lateral view of the housing of FIGS. 3a and 3b. The cutaway portion reveals the incorporated coil 160. A connecting wire 161 of the coil is connected through the opening OS to the terminal 120a, and a second connecting lead 162 is passed through the opening OS between the upper projection 150b and the lower projection 150a over the shoulder 150c to the terminal 120b on the rear side of the housing. The coil 160 may be wound onto a toroidal core. At least the inside of the opposite side wall GS may be curved to follow the curvature of the toroidal core, so that the coil 160 rests in the interior of the housing with as little play as possible. It is possible, for instance, that several windings of coil 160 are provided on the toroidal core, for instance, with a first winding being connected to the contacts 120a and 120b, and a second winding being connected to the contacts 120c and 120d. Also, it is possible that additional auxiliary windings are provided, which may be connected to additional contacts on the housing, e.g. the contacts 120e, 120f, 120g and 120h.

Furthermore, the hollow space between the coil 160 and the opening OS can be filled, at least partially, with a filling compound so as to fix the coil 160 in the housing and protect it from environmental influences. The connecting lead 162, which is passed on the outside of the housing to the rear side of the housing, may likewise be fixed by a filing compound or, for instance, a silicone adhesive.

FIG. 5 shows a modification of the embodiment according to FIG. 4, in which the electric contacts 120a and 120b are configured as THD contacts (THD: Through Hole Device). Like in FIG. 4, the bottom B of the housing has such a thickness that the electric contacts 120a and 120h can be potted therein. The electric contacts 120a and 120b are arranged laterally in the bottom B at the opening OS and on the rear wall of the housing GS or, in more general words, on the rear side of the housing, so that they project laterally out of the bottom and extend substantially parallel to the bottom surface. Other than the SMD contacts of FIG. 4, the THD contacts projecting laterally out of the bottom are kinked by an angle of about 90° so that they extend vertically to the bottom surface downstream of the kink.

1. Housing (100) for receiving an electric component, comprising
a hollow housing body (110) with an opening (OS) on one side,
a bottom (B) underneath the opening (OS),
a lid (D) above the opening (OS),
two side walls (AS1, AS2) adjacent to the opening (OS), and
at least two electric contacts (120a to 120f) provided on the bottom (B) of the housing body (110) on opposite housing sides;
wherein a first contact (120a) of the electric contacts (120a to 120f) is situated in the region of the opening (OS).

2. Housing (100) according to claim 1, wherein at least one of the two side walls (AS1, AS2) includes a guiding device (150, 151) to allow a lead (161, 162) to be fixed to the at least one of the two side walls (AS1, AS2) from the opening (OS) towards the a rear side of the housing situated opposite the opening (OS).

3. Housing (100) according to claim 1, wherein the electric contacts (120a to 120f) project laterally out of the bottom (B) and extend substantially parallel to the bottom.

4. Housing (100) according to claim 1, wherein a rear wall of the housing (GS) on a rear side of the housing is curved to follow the curvature of a coil (160), which serves as a received electric component.

5. Housing (100) according to claim 2, wherein the guiding device (150, 151) comprises two projections (150a, 150b, 151a, 151b) running in parallel so as to define an enclosure for the lead (161, 162).

6. Housing (100) according to claim 2, wherein the guiding device (150, 151) is arranged on a side facing the lid (D).

7. Housing (100) according to claim 6, wherein the two projections (150a, 150b) running in parallel extend from the opening (OS), parallel to the lid (D), laterally between a center and three quarters of the adjacent side wall (AS1, AS2), and
wherein the guiding device (150, 151) further comprises a shoulder (150c) which extends from an end of the projection (150a), facing away from the opening (OS), ramp-like in a direction of the rear side of the housing and the bottom (B) so as to extend the guiding device (150, 151) up to a second contact (120b) of the electric contacts (120a to 120f) in a region of the rear side of the housing.

8. Housing (100) according to claim 1, wherein the electric contacts (120a to 120f) are SMD contact pins which are potted with the bottom (B) of the housing body (110) in an SMD grid dimension, and wherein the housing (100) is an SMD housing for surface mounting on printed circuit boards.

9. Housing (100) according to claim 1, wherein the housing body is a single-piece molded part.

10. Electric component comprising a housing (100) according to claim 1, in which at least one coil (160) is incorporated,
wherein a first connecting lead (161) of the at least one coil (160) is electrically connected through the opening (OS) to the first contact (120a) of the electric contacts (120a to 120f) in the region of the opening (OS), and
wherein a second connecting lead (162) of the at least one coil (160) is electrically connected through the opening (OS) to a second contact (120b) of the electric contacts (120a to 120f) in the region of the rear side of the housing.

11. Electric component according to claim 10, comprising a first and a second coil,
wherein at least four electric contacts (120a to 120f) are provided in the bottom (B) on the outside of the housing body (110), wherein each first and second coil (160) is respectively assigned one electric contact (120a to 120f) on the opening (OS) and one electric contact (120a to 120f) on a rear side of the housing;
wherein a first connecting lead of the first coil is electrically connected through the opening (OS) to the first contact (120a) of the electric contacts (120a to 120f),
wherein a second connecting lead of the first coil is electrically connected through the opening (OS) via a first guiding device (150) on a first adjacent side wall (AS1) to the second contact (120b) of the electric contacts (120a to 120f) in a region of the rear side of the housing,
wherein a first connecting lead of the second coil is electrically connected through the opening (OS) to a third contact (120c) on the opening (OS) of the electric contacts (120a to 120f), and
wherein a second connecting lead of the second coil is electrically connected through the opening (OS) via a second guiding device (151) on a second adjacent side wall (AS2) to a fourth contact (120d) of the electric contacts (120a to 120f) in a region of the rear side of the housing.

12. Electric component according to claim 10, wherein at least one of the first and second coil (160) is wound onto a toroidal core, a frame core or an E-core.

13. Electric component according to claim 10, wherein a hollow space of the housing body (110) between the at least one of the first and second coil (160) and the opening (OS) is filled, at least partially, with a filling compound, subject to the standards with regard to overvoltage and contamination categories.

14. Electric component according to claim 3, wherein the electric contacts (120a, 120b) are configured as THD contacts, wherein the THD contacts projecting laterally out of the bottom are kinked by an angle of about 90° so that they extend vertically to the bottom surface downstream of the kink.

15. Electric component according to claim 8, wherein a length of the component between the opening (OS) and the rear side of the housing is substantially equal to 9.5 mm and the component is designed for safety voltages, respectively, test voltages of up to 9.5 kV.

16. A housing for receiving an electric component comprising:
a housing body having an opening, an opposing closed rear wall, a bottom, a lid, and opposing adjacent side walls extending between the opening, the opposing closed rear wall, the bottom, and the lid;
an first electric contact adjacent the opposing closed rear wall;
an second electrical contact adjacent the opening; and
a connecting lead guide extending along at least one of the opposing adjacent side walls between the opening and the opposing closed rear wall,
whereby a connecting lead extending from the first electric contact may be placed within said connecting lead guide and enter the opening connecting with an electric component within the housing extending creepage distance.

17. A housing for receiving an electric component as in claim 16 wherein:
said connecting lead guide is adjacent and extends parallel to the lid.

18. A housing for receiving an electric component as in claim 16 further comprising:
a ramp extending from the first electric contact to said connecting lead guide.
